(19) United States
(12) Patent Application Publication
(10) Pub. No.: US 2022/0234767 A1
(43) Pub. Date: Jul. 28, 2022

(54) SPHERISTRUCTURE METHOD, SYSTEM, AND APPARATUS

(71) Applicant: OMNITEQ, LLC, Houston, TX (US)

(72) Inventor: Michael David Johnson, Houston, TX (US)

(21) Appl. No.: 17/493,572

(22) Filed: Oct. 4, 2021

Related U.S. Application Data
(60) Provisional application No. 63/141,947, filed on Jan. 26, 2021.

(51) Int. Cl. B64G 1/64; B64G 1/10

(52) U.S. Cl. CPC B64G 1/64; B64G 2001/1092; B64G 1/10

(57) ABSTRACT

A structural system and a method for joining a launch vehicle and with satellites are disclosed. The method includes generating centerlines of objects requiring a connection for a structure, generating hemispheres about the centerlines, shelling of the hemispheres; performing a finite element analysis (FEA) for verifying the strength of the structure; and increasing or decreasing the thickness of the hemispheres for providing both optimal strength and minimum mass for the structure. The novel design and construction of interconnected hemispheres provide nearly the maximum physical strength for a given amount of material that could otherwise not be accomplished by utilization of a single spherical structure. In addition, the structure permits the construction of modular elements that are readily constructed using generally low-cost, simple, reliable and verifiable methods.

### CROSS-REFERENCE TO RELATED APPLICATIONS

The present application claims priority from U.S. Provisional Patent Application Ser. No. 63/141,947, filed on Jan. 26, 2021, which is incorporated herein by its entirety and referenced thereto.

### FIELD OF THE DISCLOSURE

This disclosure relates generally to a structural construction system and method utilizing a novel spherical geometric configuration employing the intersection between multiple hemispheres that readily provides support between two structural elements while simultaneously distributing structural loads throughout said structure and maximizing the overall structural strength to weight ratio while minimizing the amount of structural material and utilizing a modular, easily fabricated structure.

### BACKGROUND OF THE DISCLOSURE

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A perpetual goal in structural engineering (especially in automotive and aerospace vehicles) is to create structures that maximize the strength to weight ratio to minimize the amount of mass (weight) being moved around by the vehicle while providing sufficient strength to prevent the structure from failing under the most severe anticipated loads. This design methodology has the added advantage of (generally) minimizing the cost of materials for said structure.

It is well known in the art that hollow (hollow meaning relatively thin wall compared to the radius of the structure) spherical structures provide the minimum structural mass (assuming a uniform shell thickness) of an enclosure structure for a given volume. Said another way, hollow spherical structures provide the maximum strength to weight ratio for a given mass and volume.

Unfortunately, simple hollow spherical structures are not always possible to accomplish in practice. For example, a long, relatively thin cylindrical constraining volume (i.e. the length of the cylinder is longer than its diameter) could not accept a single hollow spherical structure to span across the cylinder ends but a series of smaller spheres, each the diameter of the bounding cylindrical volume, could be placed end to end (e.g. in a “string of pearls” fashion) to accomplish the span.

Minimal constructions are structures that minimize their surface areas given some specific constraints. The constraints could, for example, be the structural span distance or it could be the volume bounded by the structure.

A minimal surface is characterized by having a total curvature equal to zero in every point. This means that for all points on said surface, if the surface is curving with a positive value in one direction, the same point on the surface will also negative curvature to the normal direction.

It is also well known that to minimize the stresses between two joined hollow spheres one should attempt to intersect the two hollow spheres such that the intersecting circular plane diameter be approximately one half or greater the diameter of the smallest sphere of the pair. This will minimize the stress concentration (i.e. distribute the stress energy) of the loaded structure at the intersection and effectively transmit the loads through the two membranes of the attached spheres. For example, this minimum energy situation occurs in nature between the intersection of soap bubbles where the soap film tends to simultaneously minimize the surface area which simultaneously provides minimal construction.

Spherical membrane structures are also known to be difficult to fabricate for a variety of reasons. The advent of composite construction (e.g. fiberglass or carbon fiber/epoxy resin binder), injection molding, stamped sheet metal fabrication and 3-D printing technologies reduces the complexity of fabricating spherical structures but there is still a limit, particularly in capital costs, of the size of structure that can be fabricated in a single piece.

The disclosed subject matter helps to avoid these and other problems in a new and novel way.

### SUMMARY OF THE DISCLOSURE

The disclosure relates to a structural construction system and method utilizing a novel spherical geometric configuration employing the intersection between multiple hemispheres that readily provides support between two structural elements while simultaneously distributing structural loads throughout said structure and maximizing the overall structural strength to weight ratio while minimizing the amount of structural material and utilizing a modular, easily fabricated structure.

According to the teachings of the present disclosure, the goal of this invention is to provide a simple method of design and construction of interconnected hemispherical (i.e. partial sphere) elements that provide nearly the maximum physical strength for a given amount of material that could otherwise not be accomplished by utilization of a single spherical structure. In addition, the invention permits the construction of modular elements that are readily constructed using generally low-cost, simple, reliable and verifiable methods.

This disclosure will utilize the following example of joining a single launch vehicle interface ring with two satellite interface rings to illustrate the fundamental concepts and advantages of the invention. However, this example is not intended to limit the invention in any way or application.

The method of design of the structure for the invention begins with (Step 1) the three-dimensional geometrical construction of drawing a normal centerline projected from the planes of the elements that are desired to be connected. Using the example, a normal centerline is drawn from the center of the satellite planes that projects towards the launch vehicle plane. A normal centerline is generated from the center of the launch vehicle plane that projects in the direction of the components to be joined.

Next (Step 2), a hemisphere is generated at each plane using the normal centerlines as the axis of rotation for each hemispherical solid and the diameter of the maximum structure attach circle equaling the diameter of the hemisphere. This is called a “minimum hemisphere”. The generated hemispheres should intersect at a set of planes that are circular in shape.

If the span distance between planes of the elements that are to be connected is greater than the sum of the hemisphere radii an additional step (Step 2a) is required. The diameter of at least one of the generated hemispheres should increase such that the intersection of the hemispheres provides a circular plane whose diameter is at least half the diameter of the smallest hemisphere in the connecting path. This can have the effect of one or more of the hemispheres to have a larger diameter “waist” between the two intersecting planes. These are termed “Larger Hemispheres”.

After this composite shape is generated using the above method, (Step 3) the solid shapes are “hollowed out” or, in Computer Aided Design (CAD) terminology “shelled” to an initial minimum material thickness estimated to provide adequate structural strength for the desired utilization of the completed structure.

If necessary, for fabrication purposes (Step 4), each of the generated hemispheres may be sliced in symmetric fashion, generally about the axis of rotation and connecting flanges generated by projecting small joining planes away from the slicing planes to generate modular subcomponents that can be readily fabricated and later joined together using fasteners, rivets, adhesives, or any other combination thereof as is well known in the art. This process adds a small amount of structural mass, but it also tremendously increases the strength of the structure by adding compound curvature.

Next (Step 5), the structure is analyzed using Finite Element Analysis (FEA) methods well known in the art to determine if the initial estimate was acceptable. If the strength of the structure is inadequate, either for too much strength (i.e. too much material) or too little strength (i.e. too little material) Steps 3 and 3a (if required) should be repeated until the desired strength is obtained.

A peculiar and extremely useful property of this process is that the resulting structure that remains after performing the above design steps should result in a structure of nearly minimum possible mass and adequate strength for the desired purpose of the structure.

Another advantage of the previous method is that it can generally result in structures that are amenable to molding fabrication processes as the shapes of the structures can be readily separated from either male or female molds.

Descriptions of certain illustrative aspects are described herein in connection with the figures. These aspects are indicative of various non-limiting ways in which the disclosed subject matter may be utilized, all of which are intended to be within the scope of the disclosed subject matter.

Other advantages, emerging properties, and features will become apparent from the following detailed disclosure when considered in conjunction with the associated figures that are also within the scope of the disclosure.

### BRIEF DESCRIPTION OF THE DRAWINGS

The present subject matter will now be described in detail with reference to the drawings, which are provided as illustrative examples of the subject matter to enable those skilled in the art to practice the subject matter. Notably, the figures and examples are not meant to limit the scope of the present subject matter to a single embodiment, but other embodiments are possible by way of interchange of some or all the described or illustrated elements and, further, wherein:

FIG. 1 is a flow chart of the novel design steps of the inventive device;

FIG. 2 illustrates the first step in the geometrical construction of the inventive device;

FIG. 3A illustrates the second step in the geometrical construction of the inventive device;

FIG. 3B illustrates an exploded view of the second step in the geometrical construction of the inventive device;

FIG. 4A illustrates the start of a third step in the geometrical construction of the inventive device;

FIG. 4B illustrates the finish of a third step in the geometrical construction of the inventive device;

FIG. 5 illustrates the fourth step in the construction of the inventive device;

FIG. 6A illustrates the start of a third alternative step in the geometrical construction of the inventive device;

FIG. 6B illustrates the finish of a third alternative step in the geometrical construction of the inventive device;

FIG. 7A illustrates an exploded view of a completed example structure of the inventive device;

FIG. 7B illustrates a completed example structure of the inventive device; and

FIG. 8 illustrates a second completed example structure of the inventive device.

### DETAILED DESCRIPTION OF ILLUSTRATIVE EMBODIMENTS

The detailed description set forth below in connection with the appended drawings is intended as a description of exemplary embodiments in which the presently disclosed process can be practiced. The term “exemplary” used throughout this description means “serving as an example, instance, or illustration,” and should not necessarily be construed as preferred or advantageous over other embodiments. The detailed description includes specific details for providing a thorough understanding of the presently disclosed method and system. However, it will be apparent to those skilled in the art that the presently disclosed process may be practiced without these specific details. In some instances, well-known structures and devices are shown in block diagram form to avoid obscuring the concepts of the presently disclosed method and system.

In the present specification, an embodiment showing a singular component should not be considered limiting. Rather, the subject matter preferably encompasses other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present subject matter encompasses present and future known equivalents to the known components referred to herein by way of illustration.

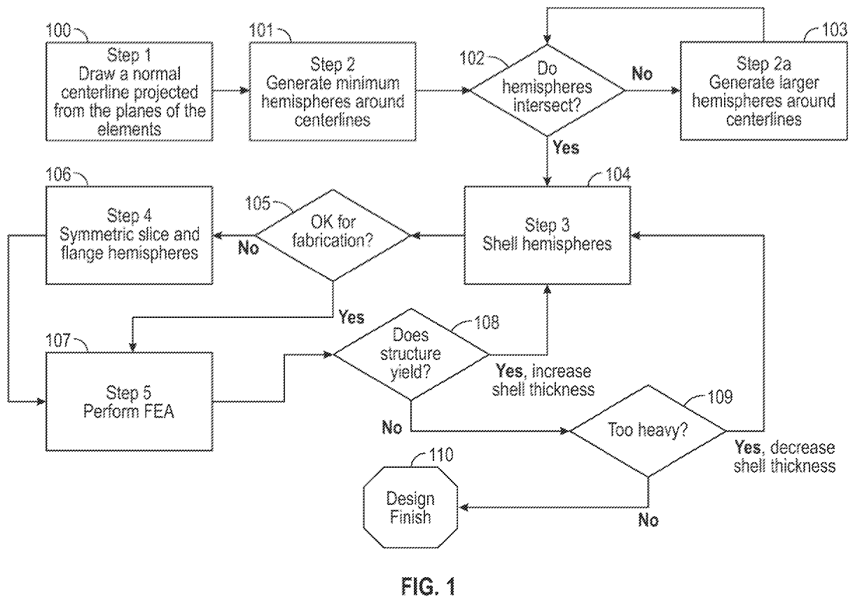

The figures herein provided, in conjunction with the written description here, clearly provide enablement of all claimed aspects of the disclosed subject matter. Accordingly, in FIG. 1 the steps of the design process of the inventive method are illustrated in a flow chart manner. The first step 100 entails construction of the centerlines of the objects requiring connecting structure. The second step 101 generates the connecting hemispheres. If the hemispheres do not connect (condition 102), an alternate second step 103 must be performed to generate larger diameter hemispheres to bridge the span distance. Once the second step 101 or 103 is performed, the third step 104, shelling of the hemispheres, is performed using an initial approximation of desired shell thickness. Condition 105, testing to see if the individual components are manufacturable (e.g. are they too large to autoclave after molding, can they be fabricated in a simple mold), routes the process either to the fourth step 106 for slicing into manageable subcomponents or to the fifth step 107. Once either third step 105 or fourth step 106 is performed the fifth step 107, FEA analysis is performed. Condition 108 is then applied (does the structure yield under maximum anticipated loads). If the structure yields the process is routed back to Step 3 (104) and the shell thickness is increased and Steps 105, 106 and 107 are repeated. As soon as the structure thickness is optimized for yield strength, the process passes through condition 109 as satisfying the minimum thickness yield condition automatically provides the minimum weight. If the process passes through condition 108 at the first pass it may be too heavy which is why it must pass through condition 109 to check for optimal mass. If the structure is too heavy the process returns to Step 3 (104) and is repeated. Once the mass and strength have been optimized, the process is complete at 110 and a finished structure has been created.

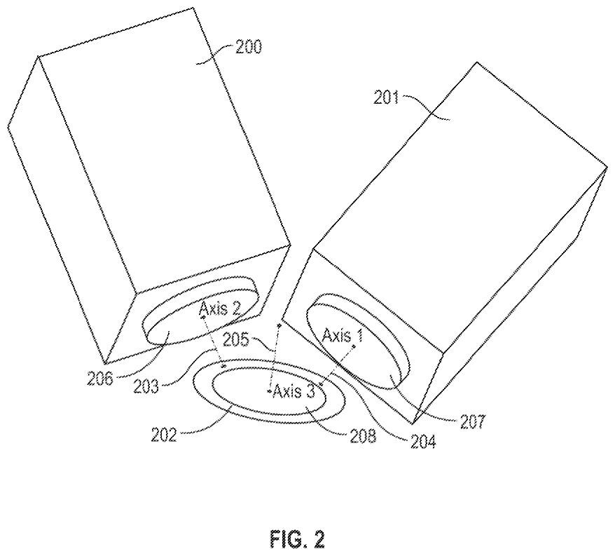

In FIG. 2, the method of design of the structure for the invention begins with (Step 1) the three-dimensional geometrical construction of drawing a set of normal centerlines 203, 204 and 205 projected from the planes 206, 207 and 208 respectively of the elements 200, 201 and 202 respectively that are desired to be connected.

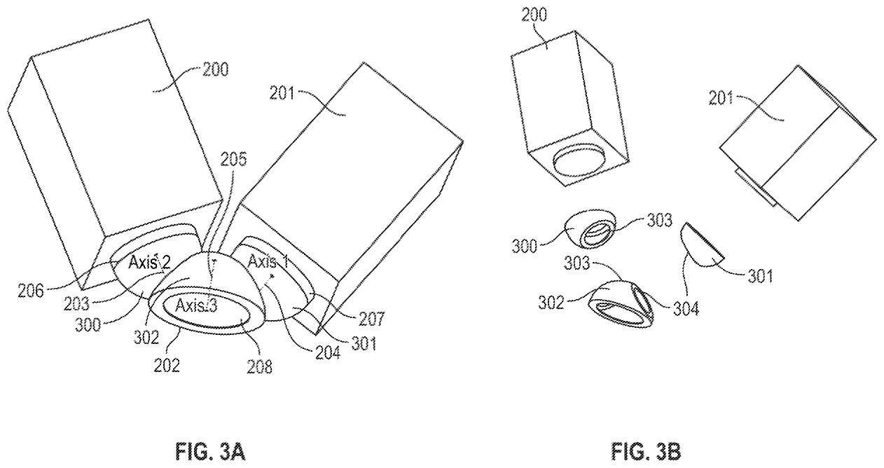

In FIG. 3A (Step 2) a hemisphere 300, 301 and 302 is generated at each plane 206, 207 and 208 respectively using the normal centerlines 203, 204 and 205 respectively as the axis of rotation for each hemispherical solid 300, 301 and 302 and the diameter of the maximum structure attach circle 206, 207 and 208 equaling the diameter of the hemispheres 300, 301 and 302. The generated hemispheres 300, 301 and 302 should intersect at a set of planes 303 and 304 that are circular in shape.

In FIG. 3B the individual components are shown in an exploded view.

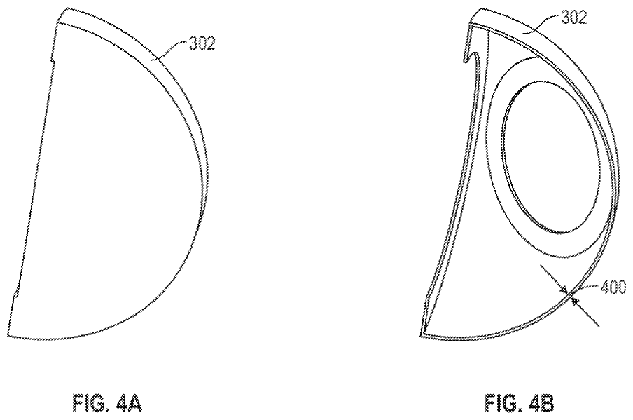

In FIG. 4A (cutaway view) after this composite solid shape 302 is generated using the above method. In cutaway view FIG. 4B (Step 3) the solid shape 302 is “hollowed out” or, in Computer Aided Design (CAD) terminology “shelled” to an initial minimum material thickness 400 estimated to provide adequate structural strength for the desired utilization of the completed structure.

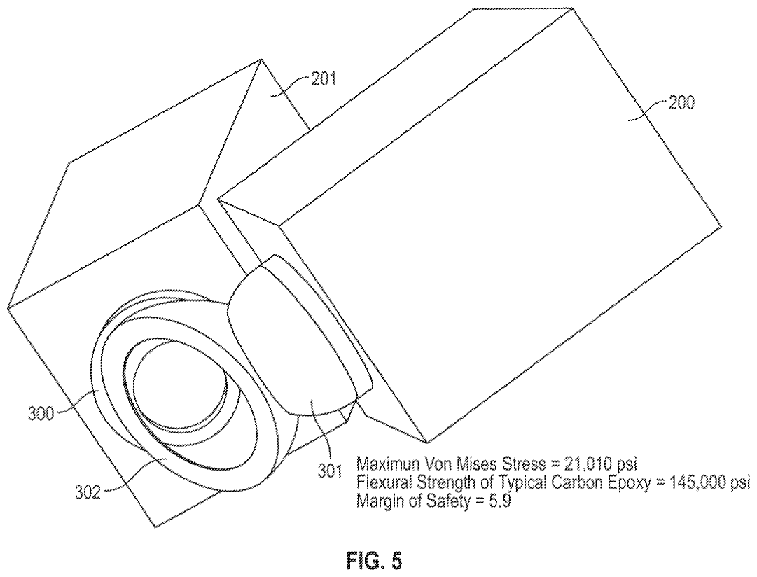

In FIG. 5 the structure is analyzed using Finite Element Analysis (FEA) methods well known in the art to determine if the initial estimate was acceptable. If the strength of the structure is inadequate, either for too much strength (i.e. too much material) or too little strength (i.e. too little material) blocks 104 through 109 in FIG. 1 (if required) should be repeated until the desired strength is obtained.

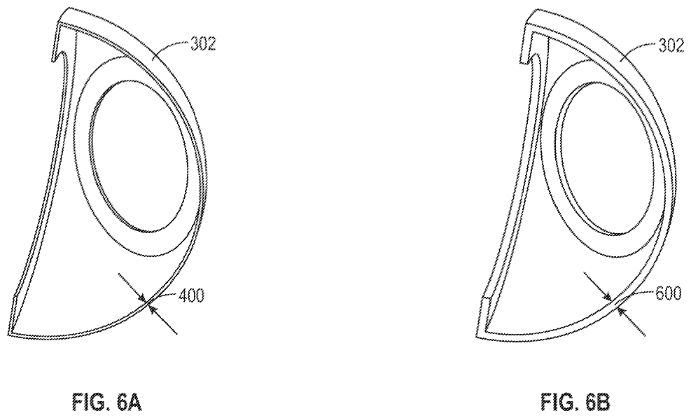

In cutaway view FIG. 6A, the initial shelled structure 302 of shell thickness 400 may be increased in strength if required after initial FEA analysis by simply increasing the shell thickness as shown in cutaway view FIG. 6B. Shelled structure 302 has increased its shell thickness 600 to impart additional strength to the structure to accommodate operational loads.

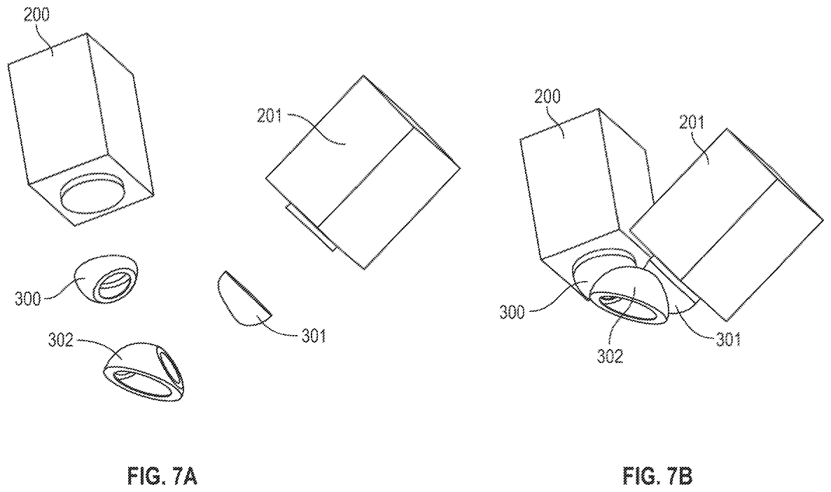

A peculiar and extremely useful property of this process is that the resulting structure that remains after performing the above design steps should result in a structure of nearly minimum possible mass and adequate strength for the desired purpose of the structure as illustrated in exploded view FIG. 7A and assembled view FIG. 7B.

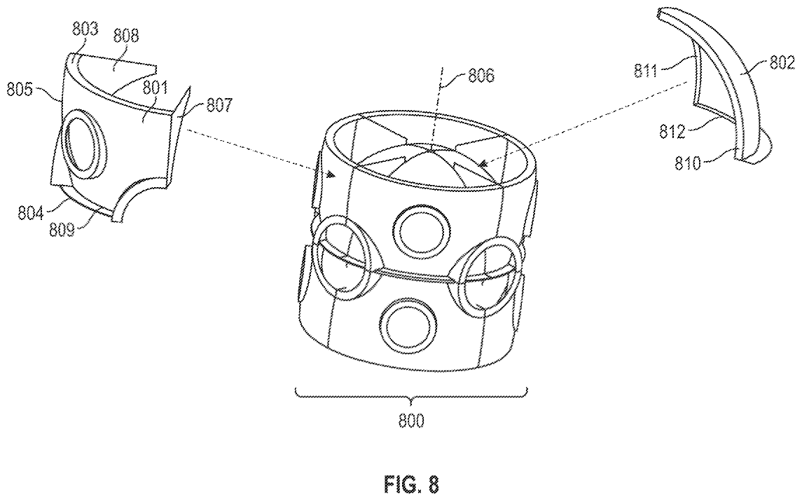

As shown in FIG. 8, another advantage of the previous method is that is can generally result in structures 801 and 802 that are amenable to molding fabrication processes as the shapes of the structures 801 and 802 can be readily separated from either male or female molds.

Also in FIG. 8 condition 102 (from FIG. 1) is illustrated since the span distance between planes 803 and 804 of the elements that are to be connected is greater than the sum of the hemisphere radii an additional step is required. The diameter of at least one of the generated hemispheres should increase such that the intersection of the hemispheres provides a circular plane whose diameter is at least half the diameter of the smallest hemisphere in the connecting path. This can have the effect of one or more of the hemispheres to have a larger diameter “waist” 805 between the two intersecting planes.

In FIG. 8, if necessary, for fabrication purposes (Step 3a), each of the generated hemispheres may be sliced in symmetric fashion, generally about the axis of rotation 806 and connecting flanges 807/808/809 for part 801 and 810/811/812 for part 802 generated by projecting small joining planes away from the slicing planes to generate modular sub components 801 and 802 that can be readily fabricated and later joined together using fasteners, rivets, adhesives or any other combination thereof as is well known in the art. As shown in FIG. 8, eight external structure parts 801 form the outer structure of assembly 800 and eight tank structure parts 802 form an internal spherical tank. This process adds a small amount of structural mass, but it also tremendously increases the strength of the structure by adding compound curvature.

It will be apparent to those skilled in the art that various modifications and variations can be made in the present disclosure without departing from the scope or spirit of the disclosure. Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

The detailed description set forth here, in connection with the appended drawings, is intended as a description of exemplary embodiments in which the presently disclosed subject matter may be practiced. The term “exemplary” used throughout this description means “serving as an example, instance, or illustration,” and should not necessarily be construed as preferred or advantageous over other embodiments.

This detailed description of illustrative embodiments includes specific details for providing a thorough understanding of the presently disclosed subject matter. However, it will be apparent to those skilled in the art that the presently disclosed subject matter may be practiced without these specific details. In some instances, well-known structures and devices are shown in block diagram form in order to avoid obscuring the concepts of the presently disclosed method and system.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter.

What is claimed is:

1. A method of providing a structure, said method comprising the steps of:
generating centerlines of objects requiring a connection for a structure;
generating hemispheres about said centerlines;
shelling of said hemispheres;
performing a finite element analysis (FEA) for verifying the strength of said structure; and
increasing or decreasing the thickness of said hemispheres for providing both optimal strength and minimum mass for said structure.

2. The method of claim 1, wherein said hemispheres generated intersect at a set of planes that are circular in shape.

3. The method of claim 2, wherein the diameter of at least one of said hemispheres generated is made large such that the intersection of said hemispheres provides a circular plane whose diameter is at least half the diameter of the smallest hemisphere in the connecting path.

4. The method of claim 1, wherein said hemispheres are generated from each plane of said objects as the axis of rotation for each hemisphere and the diameter of the maximum structure attach circle equaling the diameter of said hemisphere.

5. The method of claim 1, further comprising, prior to performing the FEA, slicing each of said hemispheres in symmetric fashion, about the axis of rotation and connecting flanges generated by projecting small joining planes away from the slicing planes.

6. The method of claim 5, further comprising joining the sliced hemispheres.

7. A structural system, comprising:
objects; and
hemispherical membrane structures,
wherein said objects connect by intersections of said hemispherical membrane structures.

8. The structural system of claim 7, wherein said objects comprise a launch vehicle and satellites.

9. The structural system of claim 7, wherein each of said objects projects a centerline from its plane.

10. The structural system of claim 8, wherein said launch vehicle projects a centerline in the direction of planes of said satellites.

7. structural system of claim 7, wherein said objects comprise a launch vehicle interface ring and at least two satellite interface rings.

12. The structural system of claim 7, wherein said hemispherical membrane structures intersect at a set of planes that are circular in shape.

13. The structural system of claim 7, wherein each of said hemispherical membrane structures are sliced in symmetric fashion, about the axis of rotation and connecting flanges generated by projecting small joining planes away from the slicing planes.

14. The structural system of claim 13, wherein said sliced hemispherical membrane structures are joined.

15. The structural system of claim 14, wherein said sliced hemispherical membrane structures are joined using one of fasteners, rivets, and adhesives.

16. The structural system of claim 13, wherein the thickness of said hemispherical membrane structures is increased to provide optimal strength and minimum mass for said structural system.

17. The structural system of claim 13, wherein the thickness of said hemispherical membrane structures is decreased to provide optimal strength and minimum mass for said structural system.
